(19) United States
(12) Patent Application Publication
(10) Pub. No.: US 2011/0287371 A1
(43) Pub. Date: Nov. 24, 2011

(54) COMPONENT OF AN IMMERSION SYSTEM, AN IMMERSION LITHOGRAPHIC APPARATUS AND A DEVICE MANUFACTURING METHOD

(75) Inventors: Nina Vladimirovna DZIOMKINA, Eindhoven (NL); Johannes Henricus Wilhelmus Jacobs, Heeze (NL); Michel Riepen, Veldhoven (NL); Fabrizio Evangelista, Eindhoven (NL)

(73) Assignee: ASML NETHERLANDS B.V., Veldhoven (NL)

(21) Appl. No.: 13/094,243

(22) Filed: Apr. 26, 2011

Related U.S. Application Data
(60) Provisional application No. 61/328,976, filed on Apr. 28, 2010.
(60) Provisional application No. 61/385,816, filed on Sep. 23, 2010.

(51) Int. Cl. G03F 7/20; G03B 27/52; B05D 3/06

(52) U.S. Cl. 430/322; 118/429; 355/30

(57) ABSTRACT

A component of an immersion system of a lithographic apparatus is disclosed having a superhydrophobic surface which in use is not exposed to DUV radiation. Also, there is disclosed a surface of a lithographic apparatus which may come into contact with immersion liquid and is a threshold distance from a surface exposed in use to the projection beam has a superhydrophobic property.

This application claims priority and benefit under 35 U.S.C. §119(e) to U.S. Provisional Patent Application Ser. No. 61/328,976, entitled “An Immersion Lithographic Apparatus and a Device Manufacturing Method”, filed on Apr. 28, 2010, and to U.S. Provisional Patent Application Ser. No. 61/385,816, entitled “A Component of an Immersion System, an Immersion Lithographic Apparatus and a Device Manufacturing Method”, filed on Sep. 23, 2010. The contents of those applications are incorporated herein in their entirety by reference.

### FIELD

The present invention relates to a component of an immersion system, an immersion lithographic apparatus and a device manufacturing method.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of; one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

It has been proposed to immerse the substrate in the lithographic projection apparatus in a liquid having a relatively high refractive index, e.g. water, so as to fill a space between the final element of the projection system and the substrate. In an embodiment, the liquid is distilled water, although another liquid can be used. An embodiment of the present invention will be described with reference to liquid. However, another fluid may be suitable, particularly a wetting fluid, an incompressible fluid and/or a fluid with higher refractive index than air, desirably a higher refractive index than water. Fluids excluding gases are particularly desired. The point of this is to enable imaging of smaller features since the exposure radiation will have a shorter wavelength in the liquid. (The effect of the liquid may also be regarded as increasing the effective numerical aperture (NA) of the system and also increasing the depth of focus.) Other immersion liquids have been proposed, including water with solid particles (e.g. quartz) suspended therein, or a liquid with a nano-particle suspension (e.g. particles with a maximum dimension of up to 10 nm). The suspended particles may or may not have a similar or the same refractive index as the liquid in which they are suspended. Other liquids which may be suitable include a hydrocarbon, such as an aromatic, a fluorohydrocarbon, and/or an aqueous solution.

Submersing the substrate, or substrate and substrate table, in a bath of liquid (see, for example, U.S. Pat. No. 4,509,852) means that there is a large body of liquid that must be accelerated during a scanning exposure. This requires additional or more powerful motors and turbulence in the liquid may lead to undesirable and unpredictable effects.

One of the arrangements proposed is for a liquid supply system to provide liquid on only a localized area of the substrate and in between the final element of the projection system and the substrate using a liquid confinement system (the substrate generally has a larger surface area than the final element of the projection system). One way which has been proposed to arrange for this is disclosed in PCT patent application publication no. WO 99/49504. As illustrated in FIGS. 2 and 3, liquid is supplied by at least one inlet onto the substrate, desirably along the direction of movement of the substrate relative to the final element, and is removed by at least one outlet after having passed under the projection system. That is, as the substrate is scanned beneath the element in a −X direction, liquid is supplied at the +X side of the element and taken up at the −X side.

FIG. 2 shows the arrangement schematically in which liquid is supplied via inlet and is taken up on the other side of the element by outlet which is connected to a low pressure source. The arrows above the substrate W illustrate the direction of liquid flow, and the arrow below the substrate W illustrates the direction of movement of the substrate table. In the illustration of FIG. 2 the liquid is supplied along the direction of movement of the substrate relative to the final element, though this does not need to be the case. Various orientations and numbers of in-and out-lets positioned around the final element are possible, one example is illustrated in FIG. 3 in which four sets of an inlet with an outlet on either side are provided in a regular pattern around the final element. Arrows in liquid supply and liquid recovery devices indicate the direction of liquid flow.

FIG. 4 schematically depicts a further exemplary liquid supply system for use in a lithographic projection apparatus, according to an embodiment of the present invention. A liquid is supplied by two groove inlets on either side of the projection system PS and is removed by a plurality of discrete outlets, arranged radially outwardly of the inlets. In the embodiment of FIG. 4, inlets and outlets are arranged within a plate having a hole through which a beam of radiation is projected. Liquid is supplied by one groove inlet on one side of the projection system PS and is removed by a plurality of discrete outlets on the other side of the projection system PS, thereby causing a flow of a thin film of liquid between the projection system PS and the substrate W. The choice of a combination of inlet and outlet incorporated within the liquid supply system can depend on the direction of movement of the substrate W (the other combination of inlet and outlets being inactive). In the cross-sectional view of FIG. 4, arrows illustrate the direction of liquid flow out of an inlet and into the outlets.

In European patent application publication no. EP 1420300 and United States patent application publication no. US 2004-0136494, each hereby incorporated in their entirety by reference, the idea of a twin or dual stage immersion lithography apparatus is disclosed. Such an apparatus is provided with two tables for supporting a substrate. Leveling measurements are carried out with a table at a first position, without immersion liquid, and exposure is carried out with a table at a second position, where immersion liquid is present. Alternatively, the apparatus has only one table.

PCT patent application publication no. WO 2005/064405 discloses an all wet arrangement in which the immersion liquid is unconfined. In such a system substantially the whole top surface of the substrate is covered in liquid. This may be advantageous because then the whole top surface of the substrate is exposed to the substantially same conditions. This has an advantage for temperature control and processing of the substrate. In WO 2005/064405, a liquid supply system provides liquid to the gap between the final element of the projection system and the substrate. That liquid is allowed to leak over the remainder of the substrate. A barrier at the edge of a substrate table prevents the liquid from escaping so that it can be removed from the top surface of the substrate table in a controlled way. Although such a system may improve temperature control and processing of the substrate, evaporation of the immersion liquid can still occur. One way of alleviating that problem is described in United States patent application publication no. US 2006/119809 in which a member is provided which covers the substrate W in all positions and which is arranged to have immersion liquid extending between it and the top surface of the substrate and/or substrate table which holds the substrate.

### SUMMARY

In immersion lithography apparatus a droplet present on a surface otherwise uncovered by liquid will apply a heat load and may be a source of defectivity. The droplet may evaporate leaving a drying stain, it may move transporting contamination such as a particle, it may collide with a larger body of immersion liquid introducing a bubble of gas into the larger body and it may evaporate, applying a thermal heat load to the surface on which it is located. Such a heat load could be a cause of distortion and/or a source of a positioning error if the surface is associated with positioning of components of the lithographic apparatus relative to the substrate being imaged. A formation of a droplet on a surface, otherwise uncovered by immersion liquid, is therefore is undesirable.

In a localized immersion system the immersed surfaces of the lithographic apparatus are those in contact with liquid confined to a space between a projection system and surface facing the projection system, for example a substrate, a substrate table, or both (at the moment of the edge of a substrate passing underneath the projection system). Confinement of immersion liquid may be achieved using a fluid handling structure. During use, a liquid meniscus forms between the undersurface of the fluid handling structure and the facing surface. Therefore for the projection beam to be directed to a full side of the substrate under exposure, the substrate table supporting the substrate is moved relative to the projection system. To maximize the output of substrate exposed by the apparatus, the substrate table (and so substrate) is moved as fast as possible. However, there is a critical relative speed (often referred to as a critical scan speed) above which the meniscus between the fluid handling structure and the facing surface become unstable. An unstable meniscus has a greater risk of loosing immersion liquid, for example in the form of one or more droplets.

The surface of the facing surface is a non-uniform surface. Immersion liquid on the facing surface has a varied contact angle (e.g. receding contact angle) with respect to the surface for example between the substrate, the surface of the substrate table surrounding the substrate, the surface of a sensor supported by a table such as the substrate table, especially for an optical sensor the part exposed to the projection beam. Although the facing surface may be substantially planar, the facing surface may have one or more height steps (i.e. dimensional features in a direction perpendicular to the plane of the facing surface, which may be substantially parallel to the projection axis). Such a height step may be less than 100 micrometers, and could be in the range of 10 to 70 micrometers. A non-uniformity in the facing surface, for example in the form of a variable contact angle and the presence of a height step, affects the local critical scan speed. Therefore in some locations on the facing surface, the critical scan speed may briefly be exceeded, leading to an instability in the meniscus and the generation of a droplet. It is therefore desirable to provide a surface which reduces, if not minimizes, the generation of droplet and provides an increase the stability of the meniscus at higher scan speeds. In an aspect of the invention there is provided an immersion system in which a surface is provided with a superhydrophobic surface.

In an aspect of the invention there is provided a component of an immersion system of a lithographic apparatus with a superhydrophobic surface which in use is not exposed to DUV radiation.

In an aspect of the invention there is provided a lithographic apparatus comprising a substrate table to hold a substrate, a liquid handling structure to supply an immersion liquid to a space between the substrate table, and a projection system to project a radiation beam onto the substrate, wherein a surface, desirably the entire surface, of the lithographic apparatus which may come into contact with the immersion liquid and is a threshold distance from a surface exposed in use to the projection beam has a superhydrophobic property.

In an aspect of the invention there is provided a component of an immersion system of a lithographic apparatus with a structured superhydrophobic surface.

In an aspect of the invention there is provided a device manufacturing method comprising projecting a patterned beam of radiation through an immersion liquid onto a substrate supported on a table, wherein the table comprises a structured superhydrophobic surface.

In an aspect of the invention there is provided a device manufacturing method comprising projecting a patterned beam of radiation through an immersion liquid onto a substrate supported on a table, wherein a surface of the table not exposed to DUV radiation is superhydrophobic.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIGS. 2 and 3 depict a liquid supply system for use in a lithographic projection apparatus;

FIG. 4 depicts a further liquid supply system for use in a lithographic projection apparatus;

FIG. 5 depicts a further liquid supply system for use in a lithographic projection apparatus;

FIG. 6 is a schematic cross-sectional representation of a droplet on a superhydrophobic surface;

FIG. 7 is a schematic perspective representation of a surface structure;

FIG. 8 is a graphical representation of the contact angle stability of a superhydrophobic surface according to an embodiment of the present invention;

FIG. 9 is a schematic representation, in plan, of a substrate table according to an embodiment of the invention;

FIGS. 10 and 11 each show a cross-section of an encoder and table arrangement according to embodiments of the present invention;

FIG. 12 is a plan schematic view of an encoder grid according to an embodiment of the present invention;

FIGS. 13 and 14 each show a plan view of an arrangement of a bridging lane between two tables, according to embodiments of the present invention; and

FIG. 15 is a schematic perspective view of a surface structure which may be used, for example, in the arrangement shown in FIGS. 13 and 14.

### DETAILED DESCRIPTION

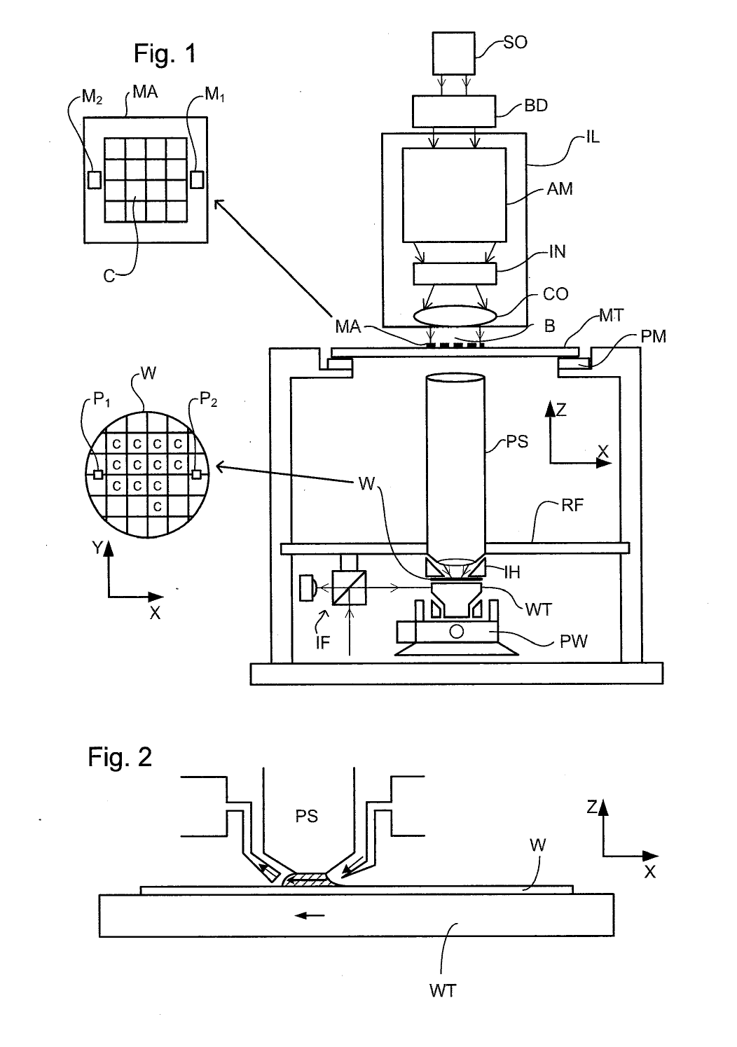

FIG. 1 schematically depicts a lithographic apparatus according to one embodiment of the invention. The apparatus comprises:
an illumination system (illuminator) IL configured to condition a radiation beam B (e.g. UV radiation or DUV radiation);
a support structure (e.g. a mask table) MT constructed to support a patterning device (e.g. a mask) MA and connected to a first positioner PM configured to accurately position the patterning device MA in accordance with certain parameters;
a substrate table (e.g. a wafer table) WT constructed to hold a substrate (e.g. a resist-coated wafer) W and connected to a second positioner PW configured to accurately position the substrate W in accordance with certain parameters; and
a projection system (e.g. a refractive projection lens system) PS configured to project a pattern imparted to the radiation beam B by patterning device MA onto a target portion C (e.g. comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The support structure MT holds the patterning device MA. It holds the patterning device MA in a manner that depends on the orientation of the patterning device MA, the design of the lithographic apparatus, and other conditions, such as for example whether or not the patterning device MA is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device MA may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two (dual stage) or more substrate tables (and/or two or more patterning device tables). In such “multiple stage” machines the additional tables may be used in parallel, or preparatory steps may be carried out on one or more tables while one or more other tables are being used for exposure.

Referring to FIG. 1, the illuminator IL receives a radiation beam from a radiation source SO. The source SO and the lithographic apparatus may be separate entities, for example when the source SO is an excimer laser. In such cases, the source SO is not considered to form part of the lithographic apparatus and the radiation beam is passed from the source SO to the illuminator IL with the aid of a beam delivery system BD comprising, for example, suitable directing mirrors and/or a beam expander. In other cases the source SO may be an integral part of the lithographic apparatus, for example when the source SO is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator IL can be adjusted. In addition, the illuminator IL may comprise various other components, such as an integrator IN and a condenser CO. The illuminator IL may be used to condition the radiation beam, to have a desired uniformity and intensity distribution in its cross-section Similar to the source SO, the illuminator IL may or may not be considered to form part of the lithographic apparatus. For example, the illuminator IL may be an integral part of the lithographic apparatus or may be a separate entity from the lithographic apparatus. In the latter case, the lithographic apparatus may be configured to allow the illuminator IL to be mounted thereon. Optionally, the illuminator IL is detachable and may be separately provided (for example, by the lithographic apparatus manufacturer or another supplier).

The radiation beam B is incident on the patterning device (e.g., mask) MA, which is held on the support structure (e.g., mask table) MT, and is patterned by the patterning device MA. Having traversed the patterning device MA, the radiation beam B passes through the projection system PS, which focuses the beam onto a target portion C of the substrate W. With the aid of the second positioner PW and position sensor IF (e.g. an interferometric device, linear encoder or capacitive sensor), the substrate table WT can be moved accurately, e.g. so as to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan.

In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions C (these are known as scribe-lane alignment marks). Similarly, in situations in which more than one die is provided on the patterning device MA, the patterning device alignment marks may be located between the dies.

The depicted apparatus could be used in at least one of the following modes:

1. In step mode, the support structure MT and the substrate table WT are kept essentially stationary, while an entire pattern imparted to the radiation beam B is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the support structure MT and the substrate table WT are scanned synchronously while a pattern imparted to the radiation beam B is projected onto a target portion C (i.e. a single dynamic exposure). The velocity and direction of the substrate table WT relative to the support structure MT may be determined by the (de-)magnification and image reversal characteristics of the projection system PS. In scan mode, the maximum size of the exposure field limits the width (in the non-scanning direction) of the target portion C in a single dynamic exposure, whereas the length of the scanning motion determines the height (in the scanning direction) of the target portion C.

3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

Arrangements for providing liquid between a final element of the projection system and the substrate can be classed into at least two general categories. These are the bath type arrangement and the localized immersion system. In the bath type arrangement substantially the whole of the substrate and optionally part of the substrate table is submersed in a bath of liquid. The so called localized immersion system uses a liquid supply system in which liquid is only provided to a localized area of the substrate. In the latter category, the space filled by liquid is smaller in plan than the top surface of the substrate and the area filled with liquid remains substantially stationary relative to the projection system while the substrate moves underneath that area.

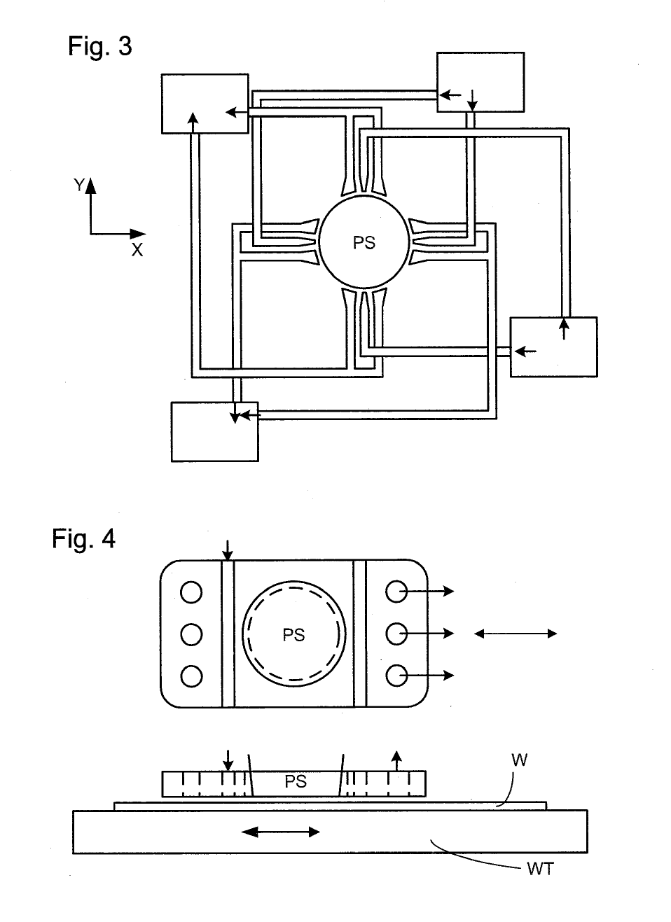

A further arrangement, to which an embodiment of the present invention is directed, is the all wet solution in which the liquid is unconfined In this arrangement substantially the whole top surface of the substrate and all or part of the substrate table is covered in immersion liquid. The depth of the liquid covering at least the substrate is small. The liquid may be a film, such as a thin film, of liquid on the substrate. Any of the liquid supply devices of FIGS. 2-5 may be used in such a system; however, sealing features are not present, are not activated, are not as efficient as normal or are otherwise ineffective to seal liquid to only the localized area.

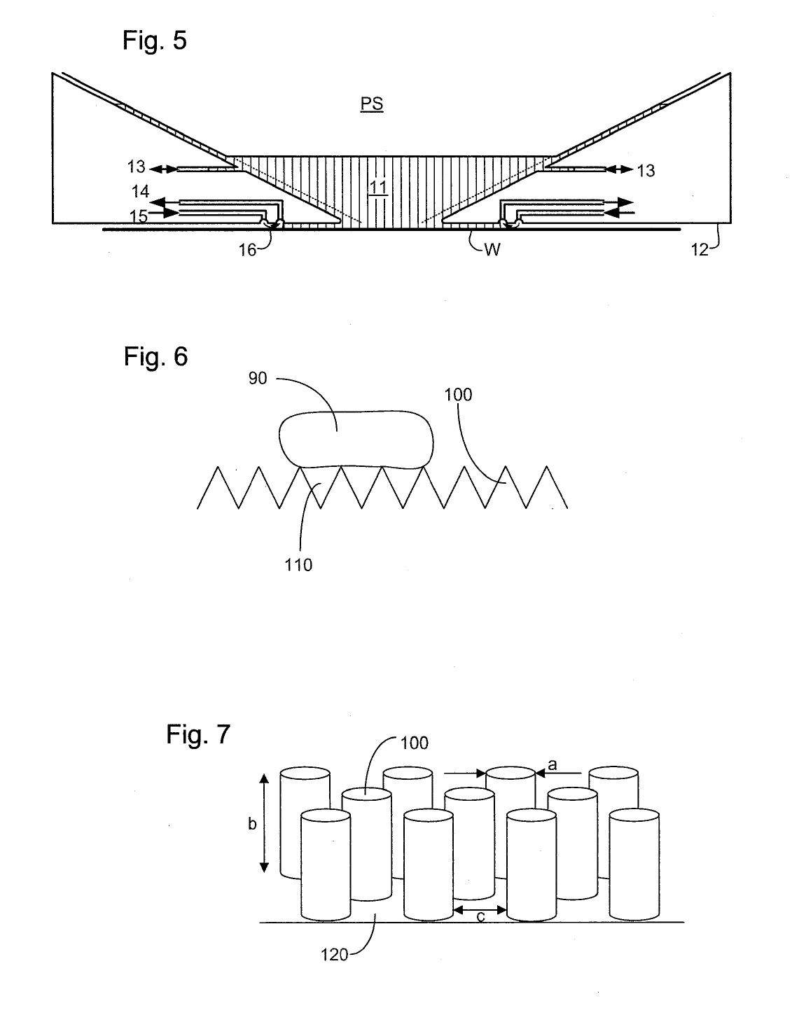

Four different types of localized liquid supply systems are illustrated in FIGS. 2-5. The liquid supply systems disclosed in FIGS. 2-4 were described above. Another arrangement which has been proposed is to provide the liquid supply system with a fluid confinement structure which extends along at least a part of a boundary of the space between the final element of the projection system and the substrate table. Such an arrangement is illustrated in FIG. 5.

The fluid confinement structure is substantially stationary relative to the projection system in the XY plane though there may be some relative movement in the Z direction (in the direction of the optical axis). In an embodiment, a seal is formed between the fluid confinement structure and the surface of the substrate. The seal may be a contactless seal such as a gas seal. Such a system is disclosed in United States patent application publication no. US 2004-0207824.

FIG. 5 schematically depicts a localized liquid supply system or fluid handling structure with a body 12 forming a barrier member or fluid confinement structure, which extends along at least a part of a boundary of the space 11 between the final element of the projection system PS and the substrate table WT or substrate W. (Please note that reference in the following text to surface of the substrate W also refers in addition or in the alternative to a surface of the substrate table WT, unless expressly stated otherwise.) The fluid handling structure is substantially stationary relative to the projection system PS in the XY plane though there may be some relative movement in the Z direction (in the direction of the optical axis). In an embodiment, a seal is formed between the body 12 and the surface of the substrate W and may be a contactless seal such as a gas seal or fluid seal.

The fluid handling device at least partly contains liquid in the space 11 between a final element of the projection system PS and the substrate W. A contactless seal, such as a gas seal 16, to the substrate W may be folined around the image field of the projection system PS so that liquid is confined within the space 11 between the substrate W surface and the final element of the projection system PS. The space 11 is at least partly formed by the body 12 positioned below and surrounding the final element of the projection system PS. Liquid is brought into the space 11 below the projection system PS and within the body 12 by liquid inlet 13. The liquid may be removed by liquid outlet 13. The body 12 may extend a little above the final element of the projection system PS. The liquid level rises above the final element so that a buffer of liquid is provided. In an embodiment, the body 12 has an inner periphery that at the upper end closely conforms to the shape of the projection system PS or the final element thereof and may, e.g., be round. At the bottom, the inner periphery closely conforms to the shape of the image field, e.g., rectangular, though this need not be the case.

The liquid may be contained in the space 11 by the gas seal 16 which, during use, is formed between the bottom of the body 12 and the surface of the substrate W. The gas seal 16 is formed by gas, e.g. air or synthetic air but, in an embodiment, N₂ or another inert gas. The gas in the gas seal 16 is provided under pressure via inlet 15 to the gap between body 12 and substrate W. The gas is extracted via outlet 14. The overpressure on the gas inlet 15, vacuum level on the outlet 14 and geometry of the gap are arranged so that there is a high-velocity gas flow inwardly that confines the liquid. The force of the gas on the liquid between the body 12 and the substrate W contains the liquid in a space 11. The inlets/outlets may be annular grooves which may surround the space 11. Each annular groove may be continuous or discontinuous. The flow of gas is effective to contain the liquid in the space 11. In the cross-sectional view of FIG. 5, arrows illustrate the direction of fluid flow in and out of the body 12.

The example of FIG. 5 is a so called localized area arrangement in which liquid is only provided to a localized area of the top surface of the substrate W at any one time. Other arrangements are possible, including fluid handling systems which make use of a single phase extractor (whether or not it works in two phase mode) as disclosed, for example, in United States patent application publication no. US 2006-0038968.

In an embodiment, a single phase extractor may comprise an inlet which is covered in a porous material which is used to separate liquid from gas to enable single-liquid phase liquid extraction. A chamber downstream of the porous material is maintained at a slight under pressure and is filled with liquid. The under pressure in the chamber is such that the meniscuses formed in the holes of the porous material prevent ambient gas from being drawn into the chamber. However, when the porous surface comes into contact with liquid there is no meniscus to restrict flow and the liquid can flow freely into the chamber. The porous material has a large number of small holes, e.g. of diameter in the range of 5 to 50 μm. In an embodiment, the porous material is at least slightly lyophilic (e.g., hydrophilic), i.e. having a static contact angle of less than 90° relative to the immersion liquid, e.g. water.

Another arrangement which is possible is one which works on a gas drag principle. The so-called gas drag principle has been described, for example, in United States patent application publication no. US 2008-0212046 and United States patent application publication no. 2009/0279060. In that system the extraction holes are arranged in a shape which desirably has a corner. The corner may be aligned with the stepping and scanning directions. This reduces the force on the meniscus between two openings in the surface of the fluid handing structure for a given speed in the step or scan direction compared to if the two outlets were aligned perpendicular to the direction of scan.

An embodiment of the invention may be applied to a fluid handling structure used in all wet immersion apparatus. In the all wet embodiment, fluid is allowed to cover the whole of the top surface of the substrate table, for example, by allowing liquid to leak out of a confinement structure which confines liquid to between the final element of projection system and the substrate. An example of a fluid handling structure for an all wet embodiment can be found in United States patent application publication no. US 2010/0060868.

In all types of immersion lithographic apparatus and liquid handling structures, one or more lyophobic surfaces may be used to assist in controlling the immersion liquid. A lyophobic surface is a surface on which liquid, e.g. immersion liquid such as in the form of a droplet, will exhibit a high contact angle. For example, in an embodiment a lyophobic surface is a surface on which liquid will exhibit a receding contact angle of greater than 60°. In an embodiment the receding contact angle of liquid on the surface may be greater than 70°, greater than 75°, greater than 80° or greater than 90°. (Note that although the contact angle is in reference to a liquid on a surface, reference is sometimes made in this description to a contact angle of a surface. It is intended that such references are to the properties of the surface which determine the contact angle of liquid on the surface). For present purposes, a film covering all or a substantial part of a surface is considered a droplet.

A high receding contact angle is desirable in some cases because the critical scan speed that is the highest scan speed at which substantially no liquid loss is observed, increases with receding contact angle of the surface that is being scanned underneath the immersion liquid. Critical scan speed may also depend upon the shape, size and design of the liquid handling structure and scan length but for a given handling structure, the critical scan speed is generally higher with higher receding contact angle. It is also desirable for the top surface of the substrate table WT surrounding the substrate W to have a receding contact angle the same as or higher than the receding contact angle of the substrate W. This enables the scan speed to be set at the maximum permitted by the substrate W with substantially no liquid loss occurring when the scan passes over the edge of the substrate W. For moves of the substrate table WT between imaging of the substrate and imaging of a sensor or imaging of the next substrate (so called avoidance moves) are desirably carried out as fast as possible to reduce or minimize any throughput loss. Therefore if the speed of the substrate table WT when a surface passes under the projection system PS during such avoidance moves can be increased, this is advantageous. By increasing the receding contact angle of the substrate table WT on such areas the speed of avoidance moves can be increased. The receding contact angle of liquid on the substrate W may depend on the resist or any topcoat used. For maximum versatility, it is desirable that the surface of a substrate table WT surrounding the substrate have a receding contact angle of greater than or equal to known resists and topcoats. Known resists and topcoats have receding contact angles for water of, for example, 69°, 75° and 81°. More recent resists have tended to provide a higher receding contact angle and it is presently anticipated that resists will be developed in the future having still higher receding contact angles.

The contact angle may be measured dynamically at room temperature (20° C.) and atmospheric pressure. Water contact angles may be determined with any type of goniometer, for example a FTA 200 Dynamic Contact Angle Analyser (available from Camtel Ltd, Elsworth, Cambridgeshire, UK) at room temperature.

Hydrophobic coatings are used in immersion lithography on the surfaces of the immersion system to help control immersion liquid confinement. Known hydrophobic surfaces currently permit a scan speed of 1 m/s scan speed. However, the speed of relative movement between the substrate table WT and the projection system PS can be in excess of this speed, for example a 3 m/s scan speed.

A stable receding contact angle (RCA) of a current hydrophobic surface, such as a coating, is 75 degrees. The RCA can be further tuned and a stable receding contact angle can be achieved in the order of 80-85 degrees. Depending on the design of immersion system, the highest speed on the substrate table WT that can be achieved at these contact angles is approximately 1 m/s. To achieve a faster speed with a stable meniscus, a stable receding contact angle of, for example, the substrate table WT would need to exceed 80 degrees.

A superhydrophobic surface may allow one easily to achieve RCA above 130 degrees. Common values for superhydrophobic surfaces are in the range of 140-150 degrees. These values are achieved by structuring an existing surface (2D structure) or applying a colloidal particle in order to form a 3D structure (see, e.g., “Progress in Superhydrophobic Surface Development” by Paul Roach, Neil J. Shirtcliffe and Michael I. Newton, Soft Matter, 2008, 4, 224-240 which is hereby incorporated by reference in its entirety). The microstructure accentuates the contact angle of the surface, so that a lyophobic surface becomes even more lyophobic. The material used to provide the surface may be the material of the respective component, a coating or an adherable planar surface, e.g. a sticker.

Water on a nano-structured polymethylmethacrylate (PMMA) surface has been considered to examine dynamic contact line behavior as compared to a contact line behavior on a smooth hydrophobic surface as well as transitions therebetween.

Three different surfaces were examined to compare their respective dynamic contact line behavior on a turn table system, built to mimic an immersion system used in a lithographic scanning apparatus. The surfaces were: 1) a hydrophobic surface with a static contact angle of about 110°, hysteresis ˜35°, 2) a rough hydrophobic surface with a static contact angle of about 135-140°, hysteresis ˜30-50°, and 3) a water repellent structured superhydrophobic surface with a static contact angle of 150° and hysteresis <5°.

Dynamic behavior of a contact line on a hydrophobic surface has been studied with a turn table and has been reported previously (Michel Riepen et al., Proceedings of the 1^{st} European Conference on Microfluidics—Microfluidics 2008—Bologna, Dec. 10-12, 2008, which is hereby incorporated by reference in its entirety). However the dynamic contact angle behavior of a superhydrophobic surface at a high velocity (e.g., greater than 1 m/s) has not. Use of a hydrophobic coating on a rough surface is disclosed in United States patent application publication no. US 2010-0279232.

On the hydrophobic surface, the instability of the receding contact line occurred at the critical velocity of ˜0.8 m/s. On a rough hydrophobic sticky surface there were no instabilities on the receding contact line even at high system velocity of 2.5 m/s. The superhydrophobic surface also showed a stable contact line up to 2.5 m/s. A water droplet on the rough hydrophobic and superhydrophobic surface exhibited no difference between an advancing and receding angle. It was observed that instabilities on the receding contact line were unaffected by height of the droplet.

It has therefore been determined that water droplets easily slip or roll down on a superhydrophobic surfaces without shedding water (or without water loss). It is noted that even a small roughness (e.g. structured roughness) would improve the maximum stable scanning velocity over a smooth hydrophobic film.

A structured surface is not the same as a rough surface with random roughness. A structured surface may be a surface in which a gas gap is present under immersion liquid on the surface. Liquid 90 passing over a superhydrophobic structured surface may form a meniscus which contacts only raised portions 100 of the surface, as shown in FIG. 6, forming a gas gap 110 between the liquid 90 within the meniscus and the structured surface. In other words, the structure of the surface is such that immersion liquid forms a stable composite interface on the surface with gas pockets or a gas gap 110 between solid and liquid 90. A gas gap 110 may be beneficial because it may reduce the thermal load applied to the structured surface as the liquid 90 passes over the surface. The thermal load applied to the surface by the liquid 90 is limited to the portions of the surface in contact with the liquid 90. So although the liquid 90 may evaporate, the heat load applied to the surface is reduced, if not minimized.

A droplet of liquid 90 may affect the thermal stability of the surface on which it is located. A superhydrophobic structured surface, whether coated, provided by an adherable planar surface (i.e. sticker) or as a structured surface of the material making up the body, may act as a thermal isolator. A sticker may be made of thermally insulating material.

Because the thermal conductance of ambient air is about 0.025 W/m/K (where ambient air is the gas in the immersion system), and the thermal conductance of the material used to make the superhydrophobic structured surface (which may be a sort of plastic) is in the range of 0.2 to 1 W/m/K, it can be seen that there is at least an order of magnitude in gain in thermal isolation by using a microstructured superhydrophobic surface compared to a planar surface.

A superhydrophobic surface reduces, if not prevents, liquid staying on the surface. By preventing, or restricting, liquid remaining on the surface, evaporation of liquid on the surface is reduced, reducing the thermal load applied to the surface. There may be less cooling of the surface. Cooling of the surface, especially localized cooling such as caused by evaporation of a liquid droplet particularly if irregularly located, is undesirable as it leads to thermal distortion of the surface.

In an embodiment the structured surface has, in plan, an irregular or a regular repeating pattern. The pattern may be, in plan, two dimensional. An example of a regular pattern is illustrated, in perspective view, in FIG. 7. The embodiment of FIG. 7 is, in plan, a two dimensional pattern. However, the structure may have, in plan, a one dimensional pattern as illustrated, for example, in FIG. 15.

In an embodiment, the structure comprises a plurality of projections 100 with troughs 120 between adjacent projections 100. As described above with reference to FIG. 6, the sizes and relative dimensions of the projections 100 and troughs 120 are such that liquid forms a stable composite interface on the surface with gas pockets 110 (in the troughs 120) between solid and liquid. This results in a superhydrophobic surface with a static contact angle of about 150° and hysteresis of less than 5°. These kinds of structures are disclosed in “Progress in Superhydrophobic Surface Development” by Paul Roach, Neil J Shirtcliffe and Michael I. Newton in Sofimatter 2008, 4, 224-240 and “Contact Angle, Adhesion and Friction Properties of Micro-and Nanopatterned Polymers for Superhydrophobicity” by Yong Chae Jung and Bharat Bhushan in Nano Technology 17 (2006) 4970-4980 which documents are hereby incorporated in their entirety by reference.

In an embodiment the depth of the troughs 120 (illustrated by dimension b in FIG. 7) is between 100 nm and 50 μm, optionally between 100 nm and 10 μm. In an embodiment the depth of the troughs is between 200 nm and 2 μm. Typically a ratio of the maximum plan dimension of the projections (dimension a illustrated in FIG. 7) to trough depth b is between 1:1-1:4 or between 1:1.5-1:3 or 1:2 to 1:3. A ratio of 1:2 is desirable. In an embodiment the maximum plan dimension of the projections a is equal to or greater than the distance between adjacent projections (illustrated as distance c in FIG. 7). Such dimensions help to form a stable composite interface with gas pockets 110 between solid and liquid.

In an embodiment, the structured surface is a surface with a roughness factor Rf of 1 or more (roughness factor is the ratio of the solid-liquid area (A(SL)) to its projection on the flat plane (A(F))). In an embodiment, the structured surface is a surface with a fraction flat geometrical area of the liquid-gas interface under the droplet f(LA) of less than 0.4. The Rf and f(LA) are measured when the contact angle of liquid on the surface to the hydrophobic layer on top of the structure is above 100 degrees (above 110 degrees or up to 120 degrees) measured on a smooth surface. In an embodiment, Rf is less than 1.5 (desirably close to 1). In an embodiment, f(LA) is between 0.4 and 0.6. In an embodiment the width of the projection in plan (W(F)) divided by the height of the projection (H) is less than 1 (desirably less than 0.6). In an embodiment W(F) is in the range of 50 nm to 50 μm (desirably less than 20 μm, less than 10 μm, less than 5 μm or less than 1 μm). These features may be relevant for assessing the quality of the hydrophobic coating (with respect to receding contact angle) which is applied to the structured surface. A coating of low quality could prevent superhydrophobicity from being achieved. In an embodiment, a hydrophobic coating of suitable quality would have a receding contact angle of 60 degrees or more, desirably 80 degrees or more.

Low contact angle hysteresis results in a low water roll off-angle (i.e. an angle at which a surface needs to be relative to horizontal for water to roll off the surface under gravity).

In an embodiment, the structure is formed in the material of the component on which the surface is provided. A conformal hydrophobic coating may then be applied over the structured surface.

The structure may be formed by any method including, for example, etching.

In an embodiment the structure is formed in ceramic or glass material or in a poly(methylmethacrylate) (PMMA) or polydimethylsiloxane (PDMS) polymer by a dry etching process followed by deposition of a hydrophobic coating. In an embodiment, a structured surface made from PMMA or PDMS exhibits hydrophobicity only when coated with a hydrophobic coating.

In an embodiment the thickness of the applied coating is less than 100 nm desirably less than 40 mn, e g. in the range of 1 to 20 nm.

In an embodiment the coating is applied to the surface and then the structure is formed in the coating.

In an embodiment a planar adherable member (e.g. a sticker) has a structure formed in it and is adhered to the component to form the structured surface. In an embodiment the adherable member is comprised of poly(methyl methacrylate) or polytetrafluoroethylene (PTFE). In an embodiment, a surface made from PTFE material may exhibit hydrophobicity without a hydrophobic coating. A height step may be formed by the edge of an adherable planar member applied to an underlying surface. The height of the adherable planar member may have the same dimensions of the height step. An adherable planar member may have a height dimension of between 10 to 70 μm, i.e. more than 10 μm, less than 70 μm, for example 20 μm.

In an embodiment the structure is formed by laser etching, for example laser ablation of a PTFE surface.

In an embodiment the structure is applied by deposition of colloidal particles. For example, the coating may be formed by particles. The particles may have a diameter of less than 500 nm or less than 200 nm In an embodiment, the particles have a diameter of less than 50 μm, desirably less than 20 μm. Such a particle size range is consistent with the size range of features of the structure, for example the trough depth and/or trough width. The particles may be generally spherical in shape. An example of a colloidal particulate deposit is a deposit of colloidal silica.

As will be appreciated, the structures described above are microstructured or nanostructured surfaces.

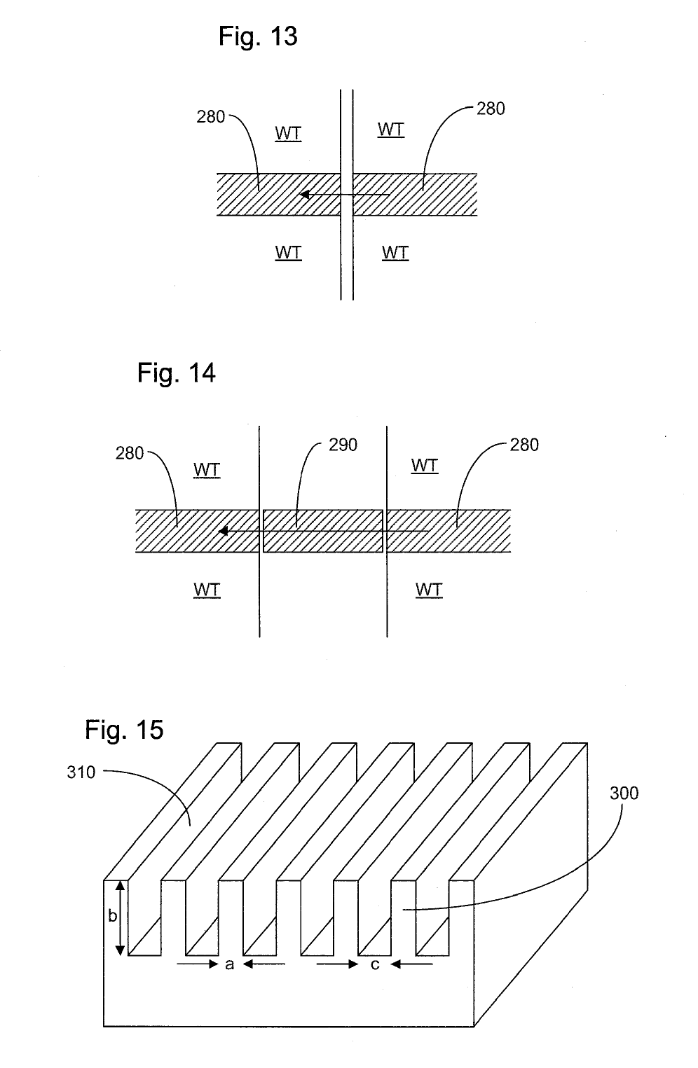

The structure may be a unidirectional structure, as described below with reference to FIGS. 13-15.

In an embodiment, the projections 100 have a cross-section (both in terms of shape and size) which is substantially constant along their length in a direction parallel to the plane of the surface.

Certain surfaces of a lithographic apparatus are routinely exposed to the DUV radiation of the beam used to pattern the lithographic substrates. A structured surface may degrade more quickly than a smooth surface, especially it the surface is made from an organic material, like a sticker. In the event of degradation, the sticker may be replaced.

Some surfaces are exposed to damaging radiation so much that the lifetime of a superhydrophobic surface at that location may be restricted. Such surfaces include the substrate surface (which is determined by the customer), the substrate table surface surrounding the substrate which is exposed, for example, during exposure of an edge portion of the substrate, a sensor surface such as a projection sensor (for example, a transmission image sensor, a projection system interferometer (ILIAS), a dose sensor, and/or a spot sensor). It is therefore desirable to realize a superhydrophobicity of a hydrophobic surface not exposed to damaging radiation such as DUV radiation.

Note that if the surface of the substrate table surrounding the substrate has a superhydrophobic surface, the surface will degrade through use and it may be intermittently replaced. In an embodiment, this portion of the substrate table is not provided with a superhydrophobic surface. The surface of a sensor may have the superhydrophobic surface which degrades through use or it is provided without such a surface.

Moves of the substrate table WT under the projection system PS and moves with respect to a sensor may need to be carried out more slowly than other moves. This may be because of height differences (e.g., in the surface of the substrate table WT) at those locations can result in pinning of a meniscus which can lead to liquid loss at high speed. This may be because imaging is about to take place and the speed of movement needs to slow down to stabilize the system. At a location around a sensor a sticker may be present. Such a sticker may create a height difference and thereby be a potential source of liquid loss but the sticker itself may be hydrophobic. Therefore there may not be a need for a superhydrophobic coating at such a location. However, at another location where the projection system PS is over the substrate table WT when not imaging the substrate W or over a sensor, high speed of the substrate table WT may be desirable. For example, during movement of the substrate table WT from under the projection system PS during substrate W swap (as described below with reference to FIGS. 13-17) or during movement of a sensor under the projection system PS. Because a coating with a structured surface may be prone to fast degradation under DUV radiation, it may be desirable only to provide the structured surface to certain areas, for example areas which are not exposed to DUV radiation or areas a certain or minimum distance from exposed areas. For example, it may be desirable to provide the structured surface only to areas which come into contact with immersion liquid and are a threshold distance from a surface exposed, in use, to the beam PB.

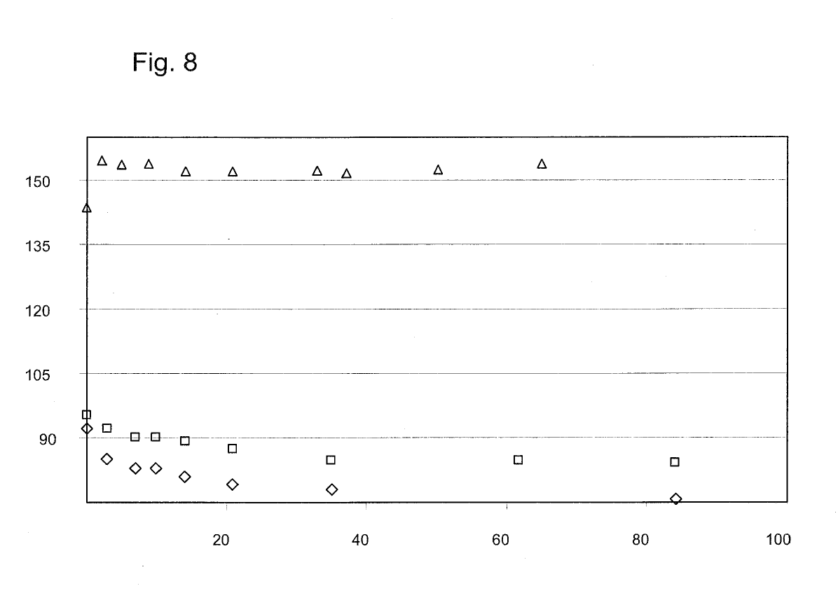

Another possible cause for degadation in the surface property of a surface is exposure to immersion liquid, such as ultrapure water. The lifetime of a lyophobic coated surface may be improved by the smoothness or uniformity of the underlying surface (see United States Patent Application Publication No. US 2010-0279232, which is incorporated herein by reference in its entirety). However, as shown in FIG. 8, the lifetime of a nanostructured surface above a receding contact angle of 120 degrees (even above 140 degrees) may be maintained for a period of at least 21, even 60, days of substantially continuous submersion in ultrapure water. FIG. 8 shows the receding contact angle for three different example coatings changing with number of days submersed in ultra pure water along the x axis. In an experiment, submersion was continued for in excess of 60 days. 21 days submersion is equivalent to around 3½ years of normal use of the apparatus. 60 days is equivalent to more than 10 years of normal use of the apparatus. A hydrophobic coating is shown with diamonds. An improved hydrophobic coating is shown with squares. A structured hydrophobic coating is shown in triangles. As can be seen, a high receding contact angle is maintained for at least 21 days and even to more than 60 days, by the coating of an embodiment of the present invention. The behavior of the measured contact angle of the example structured hydrophobic coating appears to be different from that of the example hydrophobic coating and the example improved hydrophobic coating. Whereas the contact angle of the hydrophobic coating and the improved hydrophobic coating, represented by the diamonds and squares respectively, within the first two days each decrease with time, the contact angle of the structured hydrophobic coating increases from its initial contact angle, e.g. more than 140 degrees, to a maximum, e.g. more than 150 degrees. The contact angle of the structured hydrophobic coating reduces, and then stabilizes at a contact angle of more than 150 degrees. The other two example coatings steadily decrease in contact angle. The reason for this different behavior may be as follows. During manufacture, deposits may form on the coating which reduce the contact angle. These deposits are washed off in the first couple of days. The contact angle of the coating then behaves as normal, decreasing with time through use, but at an elevated contact angle.

A surface which is exposed to damaging radiation or does not have a superhydrophobic surface, because of a lower critical scan speed, can experience liquid loss, but the effects of such a liquid loss may be counteracted by thermal conditioning and heating arrangements. These counteracting measures may be complicated, difficult to control and expensive. By applying a microstructured superhydrophobic property to a surface which is not routinely exposed to damaging radiation, liquid loss may be reduced and the need to apply a complicated thermal counter measure, such as an active heater, is alleviated. Such surfaces can include, in a non-limiting list, that of: an encoder emitter/receiver e.g. an encoder sensor 200, an encoder grid 250, a shutter member such as a closing disk CD, a bridging lane 280 or bridging element 290, the surface 240 of a substrate table WT which is a threshold distance away from the substrate W and/or sensor 210, and/or a sensor 210 (which is, for example, located on the substrate table WT or a measurement table). The surface may be the surface of an adherable planar member (such as a sticker) which may be applied (e.g. adhered) to one or more of the previously mentioned surfaces and optionally over a gap adjoining a surface to which the adherable planar member is adhered. Desirably the entire surface of the immersion system which may be in contact immersion liquid has a microstructured superhydrophobic surface.

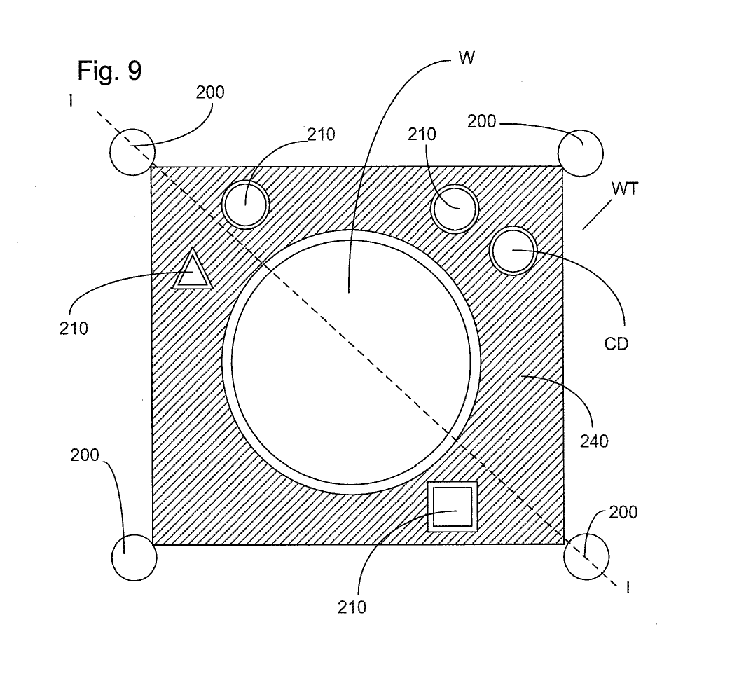

FIG. 9 shows an arrangement of substrate table WT according to an embodiment of the invention. The surfaces of the encoder sensors 200, and/or the parts of the surface 240 of the substrate table WT that are a threshold distance away from a sensor 210 and the substrate W (and illustrated in cross-hatching), are superhydrophobic. Each of the sensors 210 and the substrate table WT within the threshold distance of the substrate table WT optionally have a superhydrophobic surface. In an embodiment the substrate table WT is arranged not to support a substrate W, but it may be part of multi-stage arrangement with at least two tables and the second table may be arranged to support a substrate W.

There is a difference in surface contact angle between the superhydrophobic surface and the other parts of the substrate table WT, for example a sensor 210. When a meniscus passes between these two surfaces there is a risk of a meniscus instability and a liquid loss event. Although liquid is lost from the immersion space, restricting such events to such a boundary is desirable because it may occur near a location where an active thermal load compensating device is located and because such liquid loss will occur near these contact angle boundaries, which is a restricted part of the table surface as compared to all over the table surface.

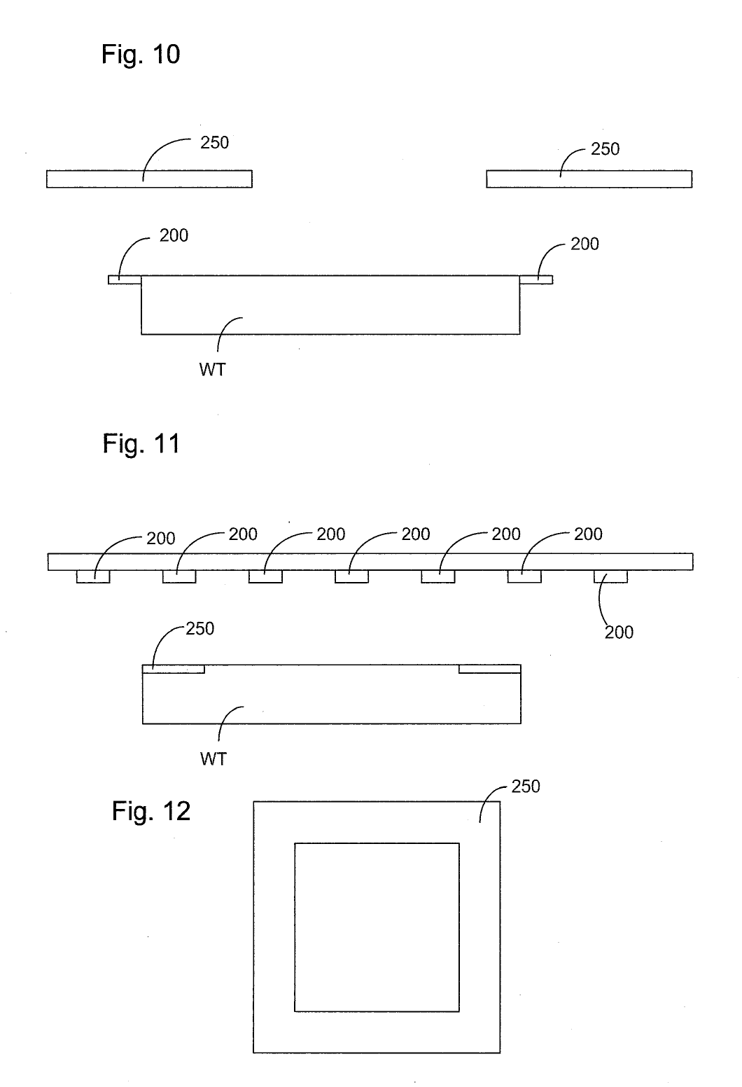

FIG. 10 shows a cross-sectional representation of the arrangement shown in FIG. 9 along the line I-I. Above the substrate table WT is an encoder reference (e.g. grid 250) which is positioned so that with the encoder sensors 200 the position of the substrate table WT, and so the substrate W, is accurately measured and may be accurately positioned. If a droplet rests on the surface of the encoder grid 250 or of the encoder sensor 200, the heat load applied to the body of the encoder grid 250 or encoder sensor 200 may be sufficiently great to prevent sufficiently accurate positioning of the substrate W relative to a component of the apparatus, such as the projection system PS. By having the surface be a superhydrophobic surface, a droplet is present on the surface a short time (due the hydrophobic nature of the surface). The thermal conductance between the surface and the droplet is reduced so that the thermal load is reduced, if not minimized. The thermal stability of the encoder may be achieved passively. It should be noted that because the surface is highly lyophobic, the chances of a droplet forming on the surface by condensation is unlikely unless, for example, the applicable part of the encoder is cooled.

FIG. 11 is another embodiment of the encoder system in which multiple sensors 200 are located above the substrate table WT and an encoder reference grid 250 is around the periphery of the substrate table WT. The surfaces of the encoder sensors 200 and/or the encoder grid 250 may be superhydrophobic.

FIG. 12 is a plan view of an encoder grid 250 which may be present above the substrate table WT or may be around the periphery of the substrate table WT.

In an embodiment the encoder system may be located under the table. For example, the encoder grid 250 may be located on the under surface of the table. One or more encoder sensors 200 may be fixed to a frame, for example it may be fitted to an arm, under the table. On relative movement between the encoder grid 250 and one or more sensors 200, the relative position of the table to the frame, e.g., a stationary frame of reference, may be determined. In another embodiment, the encoder grid 250 may be on frame and be positioned beneath the table. One or more sensors 200 on the table, for example on the undersurface of the table, may be used to measure the position of the table relative to the frame.

By having the encoder system components beneath the table, the encoder system is located a distance away from the immersion liquid supply and the immersion system. The environment may be less humid, and the risk of a droplet reaching the encoder system may be reduced. Measures may be taken actively to reduce the humidity of the environment under the table and reduce, if not prevent, passage of liquid vapor from the environment above the table to beneath the table, e.g. using a gas shower or curtain or other gas flow arrangement. However, the humidity of the environment may be greater than in a dry lithographic apparatus. To reduce the risk of a droplet forming on a component of the encoder system, at least a part, if not the entire surface, of the encoder system may be hydrophobic, desirably superhydrophobic. In an embodiment, at least a part of the undersurface and/or the side surface of the table is hydrophobic, desirably superhydrophobic.

FIGS. 13 and 14 show a bridging lane which may pass under the fluid handling structure during exchange of tables (e.g., during which the next substrate W is placed on a table for exposure). By the lane passing under the fluid handling system, liquid lost, for example, by passing through a gap between the tables may be reduced, if not minimized. The speed of movement of the table under the fluid handling system may be increased because of the increased stability of the meniscus at high contact angle. The gap may comprise a fluid extraction system to remove any escaped liquid. In FIG. 13 the tables may be brought sufficiently close to each other such that the tables may pass under the fluid handling structure with little liquid lost. In FIG. 14 a bridging element 290 is used between the tables to help ensure the immersion liquid remains confined in the immersion space. The surface of the lane on each table is superhydrophobic. The bridging element may have a superhydrophobic surface. The superhydrophobic surface may be a two-dimensional structured hydrophobic coated surface as described herein or restricting the structure in a unidirectional manner as shown in FIG. 15. Such a unidirectional surface structure, aligned with the scanning direction may allow a faster crossing of the bridging lane than with a two dimensional structure and/or a non structured hydrophobic coating. It allows scan speeds comparable to a two dimensional structure to be achieved, except the risk of gas bubble creation during crossing the gap between the bridging element 290 and the substrate table WT is lower due to a lower advancing contact angle than for a two-dimensional structure.

The unidirectional surface may be formed by, for example, in a non-limiting list: a mechanical, a chemical (e.g. etching in a material with a known crystalline structure), and/or laser technique. The unidirectional surface is a pattern of linear features, for example with a plurality of ridges 300 and grooves 310. The structure may have a pattern ratio, that should exceed ridge 300 width to height (a:b) in the range of 1:2 to 1:4, desirably 1:2, and have a ridge width exceeded by the groove width (a<c).

Parts of a lithographic apparatus where an embodiment of the invention may be applied may include a surface of: the projection system PS; a sensor 210; a substrate holder; a substrate table WT; a shutter member 290; the fluid handling structure 12; a cleaning station; a positioning feature; and/or a replaceable part.

Areas to which a superhydrophobic surface may be applied include a part of the projection system PS, for example the last optical element, e.g., lens, of the projection system PS, which is exposed to the immersion liquid. The surface may be provided in an area outside the beam path of the projection system.

The surface of the fluid handling structure 12 may be at least a part of a top surface of the fluid handing structure which may face a surface of the projection system. The surface may be at least a part of an undersurface of the fluid handling structure 12 which in use would face a substrate W, a substrate table WT or both.

The surface of a sensor 210 may be a surface of a sensor 210 which may be exposed to immersion liquid such as a transmission image sensor, a spot sensor, a dose sensor, and/or a position sensor such as an interferometric sensor or an encoder. These sensors may be intermittently exposed to immersion fluid in use. In an embodiment a coating is applied to the surface of a sensor on the substrate table WT.

The substrate holder may be used to support the substrate. The substrate table WT supports the substrate holder. In an embodiment the substrate holder is in a recess within the substrate table WT. The depth of the recess may be sized so that when a substrate is present on the substrate holder the surface of the substrate W is co-planar with the surface of the substrate table WT. When a substrate W is present on the substrate support, there may be a gap between the substrate edge and a facing edge of the substrate table WT. An embodiment of the invention may be applied to the surface of the substrate table WT, a surface of the substrate support which defines a gap, or both.

A shutter member is a component which contacts immersion liquid during, e.g., substrate swap. The shutter member is arranged to face the fluid handling structure instead of a substrate during, e.g., substrate swap to maintain immersion liquid in the immersion space 11. The shutter member may be a closing disc, measurement table or swap bridge. Note that the swap bridge may be a removable component which is in place between two tables during substrate swap to enable the fluid handling structure to be transferred from one table to another. A fluid extraction device may be located in a gap between the shutter member and the substrate table WT, such as a gap between the swap bridge and a table. The two tables can be: two substrate tables WT or a substrate table WT and a measurement table. In an embodiment a coating is applied to the surface of a closing disc CD present on the substrate table WT (shown in FIG. 9). In an embodiment a coating is applied to the surface of a swap bridge such as a body of the swap bridge or a part of the substrate table WT at a location near the swap bridge body during substrate swap.

The cleaning station, which is an example of a fluid handling structure 12, may be located on a substrate table WT or a measurement table. It may be used to clean a surface of the projection system PS which is arranged to contact immersion liquid, such as the last optical element. In an embodiment it is arranged to clean a surface of a fluid handling structure, such as a specific feature of the fluid handling structure 12 such as a liquid removal feature which may be located on the undersurface of the liquid handling structure.

The positioning feature may be used to position the substrate table WT and so the substrate W relative to the projection system PS. The positioning feature may be located on a surface of the substrate table WT, such as a periphery of the substrate table WT. In an embodiment the positioning feature is present along substantially the entire edge of the substrate table WT. The positioning feature may have graduated markings, such as a grid plate, and may be arranged for use with an encoder. A coating having a desired lyophobicity may be provided over or around the markings.

In an embodiment of the invention, a sticker may be adhered to an underlying surface to provide a surface with a specific static or receding contact angle at a location where, for example, the underlying material cannot provide a stable contact angle, the surface is difficult to coat or the surface contact angle has limited life time, so that the surface needs to be intermittently reconditioned to maintain the contact angle of the surface within specification and operational requirements. Such a sticker is an example of a replacable component. A sticker may be applied to any of the aforementioned parts.

In an embodiment, there is provided a component of an immersion system of a lithographic apparatus with a superhydrophobic surface which in use is not exposed to DUV radiation.

In an embodiment, the surface comprises a coating. In an embodiment, the surface is structured. In an embodiment, the structure of the surface is such that a gas gap is present under immersion liquid on the surface. In an embodiment, the structure of the surface is such that immersion liquid forms a stable composite interface with gas pockets between solid and liquid. In an embodiment, the structure has a regular repeating pattern. In an embodiment, the structure is in a surface of the component. In an embodiment, the component further comprises a coating on the structure to form the superhydrophobic surface. In an embodiment, the structure is a structure in a coating on the surface. In an embodiment, the structure is provided by colloidal particles on the surface. In an embodiment, the structured surface is a microstructured or nano structured surface. In an embodiment, the surface is provided by a planar adherable member. In an embodiment, the component is part of an encoder system. In an embodiment, the encoder system comprises an emitter and a mark to measure the position of the emitter relative to the mark. In an embodiment, the superhydrophobic surface is on the emitter and/or mark. In an embodiment, the component is a surface of a table comprising a sensor, or a substrate support, or both the sensor and the substrate support, the surface being at least a certain distance from the sensor and/or the substrate support. In an embodiment, the component is a bridging lane. In an embodiment, at least part of the surface comprises a unidirectional structure. In an embodiment, the unidirectional structure is elongate in a direction in which the component is intended for movement when liquid is on the bridging lane.

In an embodiment, there is provided a lithographic apparatus comprising a substrate table to hold a substrate, a liquid handling structure to supply an immersion liquid to a space between the substrate table, and a projection system to project a radiation beam onto the substrate, wherein a surface, desirably the entire surface, of the lithographic apparatus which may come into contact with the immersion liquid and is a threshold distance from a surface exposed in use to the projection beam has a superhydrophobic property.

In an embodiment, there is provided a component of an immersion system of a lithographic apparatus with a structured superhydrophobic surface. In an embodiment, the structure of the surface is such that a gas gap is present under immersion liquid on the surface. In an embodiment, the structure of the surface is such that immersion liquid forms a stable composite interface on the surface with gas pockets between solid and liquid. In an embodiment, the structured surface has, in plan, a regular repeating pattern. In an embodiment, the structure is one or two dimensional, in plan. In an embodiment, the structure comprises a plurality of projections with troughs between projections. In an embodiment, the depth of the troughs is between 100 nm and 10 μm or between 200 nm and 2 μm. In an embodiment, a ratio of the maximum plan dimension of the projections to trough depth is between 1:1-1:4 or between 1:1.5-1:3. In an embodiment, the maximum plan dimension of the projections is greater than the distance between adjacent projections. In an embodiment, the maximum plan dimension of the projections is 50 nm to 50 μm or less than 20 μm. In an embodiment, the maximum plan dimension of the projections divided by the depth of the troughs is less than 1 or less than 0.6. In an embodiment, the structure is formed in a surface of the component. In an embodiment, the component further comprises a coating on the structure. In an embodiment, the structure is formed in a coating on a surface of the component. In an embodiment, the structured hydrophobic surface is provided by a planar adherable member. In an embodiment, the structured hydrophobic surface is structured PTFE, PMMA or PDMS. In an embodiment, the surface is formed by a colloidal particulate deposit. In an embodiment, the particles of the colloidal particulate deposit have a diameter of less than 500 nm or less than 200 nm. In an embodiment, the colloidal particulate deposit is a colloidal particulate deposit of colloidal silica. In an embodiment, the structured hydrophobic surface is a microstructured or nanostructured surface.

In an embodiment, there is provided a lithographic apparatus comprising a component as described herein. In an embodiment, the lithographic apparatus is an immersion lithographic apparatus and the immersion liquid is ultra pure water.

In an embodiment, there is provided a device manufacturing method comprising projecting a patterned beam of radiation through an immersion liquid onto a substrate supported on a table, wherein the table comprises a structured superhydrophobic surface.

In an embodiment, there is provided a device manufacturing method comprising projecting a patterned beam of radiation through an immersion liquid onto a substrate supported on a table, wherein a surface of the table not exposed to DUV radiation is superhydrophobic.

It will be appreciated that the above description makes reference to a material being lyophobic, superlyophobic or lyophilic. This is relevant to any immersion liquid. In the case where the immersion liquid used is water the appropriate terms are hydrophobic, superhydrophobic and hydrophilic respectively. However, another liquid or fluid may be used as the immersion liquid. In this case the terms hydrophobic and hydrophilic should be read as being liquidphobic or liquidphilic or lipophobic or lipophilic. Similarly, hydrophobic, superhydrophobic and hydrophilic materials should be understood as disclosing, and not excluding, lyophobic, superlyophobic or lyophilic materials.

As will be appreciated, any of the above described features can be used with any other feature and it is not only those combinations explicitly described which are covered in this application.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of or about 365, 248, 193, 157 or 126 nm). The term “lens”, where the context allows, may refer to any one or combination of various types of optical components, including refractive and reflective optical components.

While specific embodiments of the invention have been described above, it will be appreciated that the invention may be practiced otherwise than as described. For example, the embodiments of the invention may take the form of a computer program containing one or more sequences of machine-readable instructions describing a method as disclosed above, or a data storage medium (e.g. semiconductor memory, magnetic or optical disk) having such a computer program stored therein. Further, the machine readable instruction may be embodied in two or more computer programs. The two or more computer programs may be stored on one or more different memories and/or data storage media.

Controllers described herein may each or in combination be operable when one or more computer programs are read by one or more computer processors located within at least one component of the lithographic apparatus. The controllers may each or in combination have any suitable configuration for receiving, processing, and sending signals. One or more processors are configured to communicate with the at least one of the controllers. For example, each controller may include one or more processors for executing the computer programs that include machine-readable instructions for the methods described above. The controllers may include data storage medium for storing such computer programs, and/or hardware to receive such medium. So the controller(s) may operate according the machine readable instructions of one or more computer programs.

One or more embodiments of the invention may be applied to any immersion lithography apparatus, in particular, but not exclusively, those types mentioned above and whether the immersion liquid is provided in the form of a bath, only on a localized surface area of the substrate, or is unconfined. In an unconfined arrangement, the immersion liquid may flow over the surface of the substrate and/or substrate table so that substantially the entire uncovered surface of the substrate table and/or substrate is wetted. In such an unconfined immersion system, the liquid supply system may not confine the immersion fluid or it may provide a proportion of immersion liquid confinement, but not substantially complete confinement of the immersion liquid.

In an immersion apparatus, immersion fluid is handled by a fluid handling system, device, structure or apparatus. In an embodiment the fluid handling system may supply immersion fluid and therefore be a fluid supply system. In an embodiment the fluid handling system may at least partly confine immersion fluid and thereby be a fluid confinement system. In an embodiment the fluid handling system may provide a barrier to immersion fluid and thereby be a barrier member, such as a fluid confinement structure. In an embodiment the fluid handling system may create or use a flow of gas, for example to help in controlling the flow and/or the position of the immersion fluid. The flow of gas may form a seal to confine the immersion fluid so the fluid handling structure may be referred to as a seal member; such a seal member may be a fluid confinement structure. In an embodiment, immersion liquid is used as the immersion fluid. In that case the fluid handling system may be a liquid handling system. In reference to the aforementioned description, reference in this paragraph to a feature defined with respect to fluid may be understood to include a feature defined with respect to liquid.

A liquid, supply system as contemplated herein should be broadly construed. In certain embodiments, it may be a mechanism or combination of structures that provides a liquid to a space between the projection system and the substrate and/or substrate table. It may comprise a combination of one or more structures, one or more fluid openings including one or more liquid openings, one or more gas openings or one or more openings for two phase flow. The openings may each be an inlet into the immersion space (or an outlet from a fluid handling structure) or an outlet out of the immersion space (or an inlet into the fluid handling structure). In an embodiment, a surface of the space may be a portion of the substrate and/or substrate table, or a surface of the space may completely cover a surface of the substrate and/or substrate table, or the space may envelop the substrate and/or substrate table. The liquid supply system may optionally further include one or more elements to control the position, quantity, quality, shape, flow rate or any other features of the liquid.

The descriptions above are intended to be illustrative, not limiting. Thus, it will be apparent to one skilled in the art that modifications may be made to the invention as described without departing from the scope of the claims set out below.

1. A component of an immersion system of a lithographic apparatus with a superhydrophobic surface which in use is not exposed to DUV radiation.

2. The component of claim 1, wherein the surface comprises a coating.

3. The component of claim 1, wherein the surface is structured.

4. The component of claim 3, wherein the structure of the surface is such that a gas gap is present under immersion liquid on the surface.

5. The component of claim 3, wherein the structure of the surface is such that immersion liquid forms a stable composite interface with gas pockets between solid and liquid.

6. The component of claim 3, wherein the structure has a regular repeating pattern.

7. The component of claim 3, wherein the structure is in a surface of the component.

8. The component of claim 7, further comprising a coating on the structure to form the superhydrophobic surface.

9. The component of claim 3, wherein the structure is a structure in a coating on the surface.

10. The component of claim 3, wherein the structure is provided by colloidal particles on the surface.

11. The component of claim 3, wherein the structured surface is a microstructured or nano structured surface.

12. The component of claim 1, wherein the surface is provided by a planar adherable member.

13. The component of claim 1, wherein the component is part of an encoder system.

14. The component of claim 1, wherein the component is a surface of a table comprising a sensor, or a substrate support, or both the sensor and the substrate support, the surface being at least a certain distance from the sensor and/or the substrate support.

15. A lithographic apparatus comprising:
a projection system configured to project a patterned beam of radiation onto a substrate;
an immersion system configured to provide liquid between the projection system and the substrate; and
a component of the immersion system having a superhydrophobic surface which in use is not exposed to DUV radiation.

16. A lithographic apparatus comprising a substrate table to hold a substrate, a liquid handling structure to supply an immersion liquid to a space between the substrate table, and a projection system to project a radiation beam onto the substrate, wherein a surface, desirably the entire surface, of the lithographic apparatus which may come into contact with the immersion liquid and is a threshold distance from a surface exposed in use to the projection beam has a superhydrophobic property.

17. A component of an immersion system of a lithographic apparatus with a structured superhydrophobic surface.

18. A lithographic apparatus comprising:
a projection system configured to project a patterned beam of radiation onto a substrate;
an immersion system configured to provide liquid between the projection system and the substrate; and
a component of the immersion system having a structured superhydrophobic surface.

19. A device manufacturing method comprising projecting a patterned beam of radiation through an immersion liquid onto a substrate supported on a table, wherein the table comprises a structured superhydrophobic surface.

20. A device manufacturing method comprising projecting a patterned beam of radiation through an immersion liquid onto a substrate supported on a table, wherein a surface of the table not exposed to DUV radiation is superhydrophobic.
